(19) United States
(12) Patent Application Publication
(10) Pub. No.: US 2010/0171484 A1
(43) Pub. Date: Jul. 8, 2010

(54) TEST INSTALLATION WITH A TEST BENCH AND METHOD FOR USING SUCH A TEST BENCH IN SAID INSTALLATION

(75) Inventors: Dominique Garreau, Labbeville (FR); Thierry Doligez, Montbazon (FR); Thierry Fernandez, Courbevoie (FR)

Correspondence Address: Perman & Green, LLP, 99 Hawley Lane, Stratford, CT, 06614, US

(73) Assignee: LABORATOIRE DES APPLICATIONS NUMERIQUES LAN, Tauxigny (FR)

(21) Appl. No.: 12/526,357

(22) PCT Filed: Feb. 8, 2008
(86) PCT No.: PCT/FR08/50193

§ 371 Date: Mar. 19, 2010

(30) Foreign Application Priority Data
Feb. 9, 2007 (FR) 07 53154

(51) Int. Cl. G01R 31/02

(52) U.S. Cl. 324/72

(57) ABSTRACT

A test installation provides for producing a residence that has a dwelling on the one hand and a test laboratory on the other. The dwelling and the laboratory are electrically powered by separate electric power supplies. The dwelling and the residence are linked to one another by sets of channels passing through a slab of the residence and opening to abutting cable trunks opposite the test laboratory. It is shown that in this way, connections joining measuring apparatus with apparatus for processing the measurements located in the test laboratory can be placed in these channels and this cable trunk. In this way, these connections are always placed correctly at the same location and do not interfere in the measurement. To increase the efficacy of the system, it is provided that a test bench is produced that is independently powered by an electrical perturbation signal that has been measured previously in the dwelling.

### CROSS-REFERENCE TO RELATED APPLICATIONS

This application is the National stage of International Application PCT/FR2008/050193 filed 8 Feb. 2008, which designated the United States of America, and which International Application was published under PCT Article 21 (s) as WO Publication 2008/104686 A3 and which claims priority from, and the benefit of French Application No. 07 53154 filed on 9 Feb. 2007, the disclosures of which are incorporated herein by reference in their entireties.

### BACKGROUND

1. Field

The subject matter of the disclosed embodiments is a test installation and a test bench, and a method for using the test bench present in this installation. The subject matter of the disclosed embodiments is to permit better characterization of the domestic electronic apparatus used in particular by private individuals or businesses, principally of the apparatus provided with remote communication functionalities. One objective of the disclosed embodiments is to contribute to better understanding of the interactions that are produced in domestic dwellings, typically between the electric household equipment such as washing machines, stovetops, ovens, or refrigerators on the one hand, and on the other hand multimedia equipment, television sets, computers, electronic games, and/or telephones, and more generally all communication items if they are connected to the domestic electric system and if they make use of power line telecommunications methods.

2. Brief Description of Related Developments

The installation of the disclosed embodiments is particularly well suited for testing the functioning of signal transmissions between the various items of equipment on power lines, as well as on the electric power supply lines. However, it can also relate to transmissions of different types, typically radio-electric, on optical fibers, or on specialized lines, for example telephone lines, especially for DSL modes.

In the field of tests, only elementary tests are known, typically using equipment in a given environment (especially in an environment by power line transmission), and measurements of the behaviors of these items of equipment in this environment. The problem presented by these elementary behavior measurements is that they are deficient in taking into account all of the situations to which the different apparatus being tested may be subjected. Furthermore, especially when it is a question of power line transmission, the network used to test the functioning of an apparatus being considered is either a perfect network, neutral, independent, equipped with all of the protections with regard to outside disturbances, or it is any network whatsoever, uncontrolled, that of a laboratory at the time the tests are performed, without having the ability to measure if problems found originate from a functional failure of the apparatus or from an inopportune failure of the electric system at the time of measurement.

The fact of producing an installation dedicated to the characterization of measuring apparatus is already in itself an improvement of the method, proceeding toward greater accuracy of carrying out measurements.

Nevertheless, experience shows that too many parameters are still uncontrolled and that reliability of the result of measurements is not achieved, leaving in doubt the perfection as far as the results presented are concerned.

### SUMMARY

In the disclosed embodiments, to solve this problem, the test installation provides for making dwellings equipped with conventional domestic apparatus and placing an electric apparatus to be tested in this installation. Because of the multiplicity of possible positions for placement of the apparatus to be tested in the dwellings, complexity of linking the apparatus to be tested to the measuring instruments that are used for this test becomes unavoidable. In effect, for example, to test a modem placed in an office, in a living room, in a kitchen, or in a lobby, it is suitable to place a measuring instrument beside the modem and to link this measuring instrument to an instrument for processing measurement signals delivered by the measuring instrument. The processing instrument itself is arranged in a test laboratory adjoining the dwelling. But these links themselves are the seat of possible radioelectric interference, making the measurement illusory.

To solve this problem the disclosed embodiments then provides for making channels in a dedicated installation at the point of each wall electric outlet to which are necessarily linked all of the items of equipment to be tested since they are electrically powered. These channels traverse a slab perpendicular to a wall outlet. They place the floor of the test dwelling where the whole installation is placed, in communication with an area beneath it, typically an area in the garage. In this garage area, there are cable trunks, in practice crossbars suspended from the ceiling of the garage in which can be placed all of the links connecting the instruments for measuring the apparatus to be tested to the instruments for processing these measurements delivered by the measuring instruments. In this way is obtained a result with greater accuracy with regard to the various possibilities for installation and for testing the equipment to be tested.

Accordingly, the subject matter of the disclosed embodiments is a test installation for the behavior of a domestic electric power supply network that has

a traditional dwelling constructed according to the rules of the art on one level, with multiple rooms,

a lower level, the garage, located beneath the floor,

with the domestic power supply network having wall electric outlets distributed within the rooms of the dwelling,

characterized in that it has

a set of open channels leading to wall outlets of the dwelling, through the slab, to cable trunks produced in the garage,

with the channels and cable trunks having connections linking measuring apparatus located close to the wall outlets to apparatus for processing the measurements.

In the same way, it is taken into account that the availability of such a test installation, definitely necessitating an edifice above a garage, would be impractical in some cases. Also, to solve this problem, it is provided to record on an electric power supply network of the test dwelling, or also of other dwellings, a protocol for utilizing and placing in service different items of equipment, especially household equipment, thus leading to the creation of perturbations on the electric network of these test dwellings. These perturbations are recorded in the form of signals, described either temporally or spectrally, or both at the same time, in a memory system for numerical data.

The signal thus produced is then used, in particular corresponding to a long period, for example of the order of a day, to guide a power supply injector. Such a power supply injector in practice has a source capable of delivering an electric power supply (typically 220 volts or 110 volts) and a regulator to modify the voltage produced by this source depending on the history of the signal measured in the course of the protocol.

Otherwise a test bench is produced, in other words in practice a panel with a multitude of power outlets, all linked to a common supply line through branches. The common line is supplied by the source regulated by the regulator. The singular feature of the panel is that all of the branches have different lengths. By way of improvement, the branches are also equipped with a branch switch to be able to create a panel with a desired number of outlets (those whose switches are turned on) and with the varied lengths of connection to the common line. Such an installation and such a method of excitation provide one possibility for developing the electric power supply network of the test panel in a way provided for in advance. One or more items of equipment to be tested are then linked to these outlets. It is also possible to reuse the protocol as frequently as desired. Accordingly, it is possible to measure the reactions of the different items of equipment in a reliable manner.

Accordingly, the subject matter to this effect is a test installation for electrical behavior that includes a laboratory, characterized in that it includes

a test bench located in the laboratory, powered by a first electric network independent of a second electric power supply network for laboratory measuring apparatus,

in the bench, an electrical distribution panel equipped with a set of outlets,

with each outlet being linked to the first network through a branch,

with each branch being in series with a branch switch,

with the lengths of the branches being different to simulate with this test bench a behavior analogous to that of an electrical network to be tested.

The subject matter also comprises a method for measuring the behavior of an electrical apparatus characterized in that it includes the following steps

the development of an electric power supply is measured in a network with a test laboratory,

the signal of this electric power supply is stored in memory with a broadband recorder, and

it is injected into a control network of the test laboratory equipped with a test bench to which is connected the electrical apparatus whose behavior is to be measured.

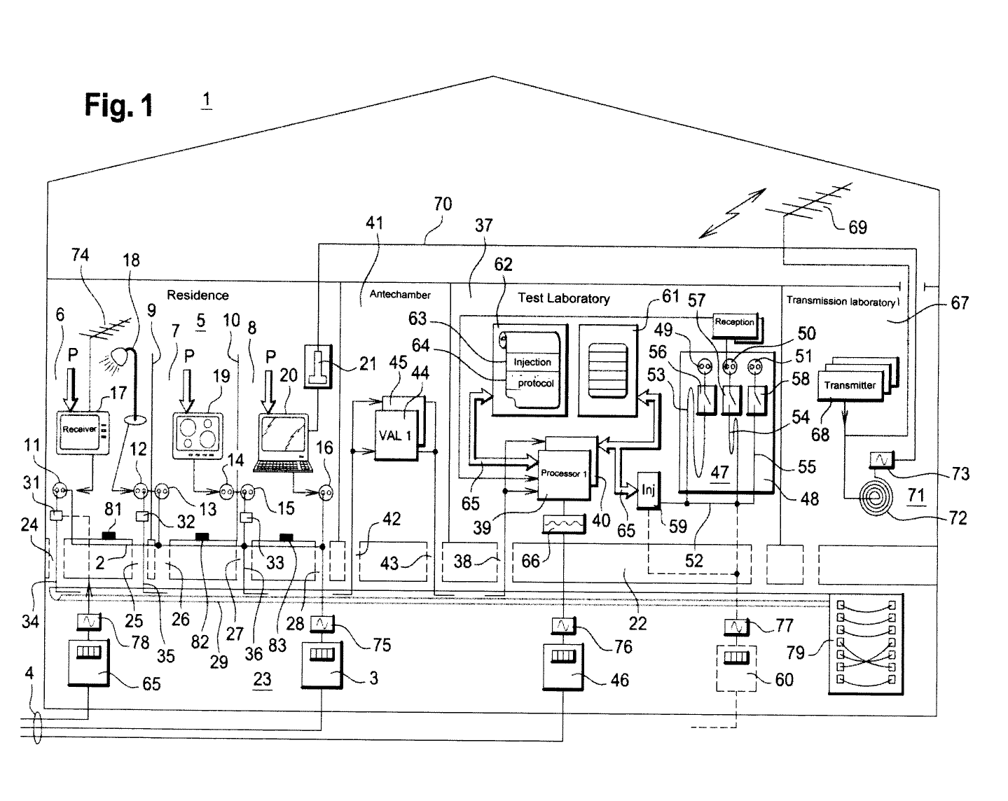

The disclosed embodiments will be better understood by reading the following description, and examining FIG. 1 that accompanies it. These are given only by way of illustration and do not at all limit the disclosed embodiments. FIG. 1 shows a test installation, a test panel, and a test method pursuant to the disclosed embodiments.

### DETAILED DESCRIPTION OF THE DISCLOSED EMBODIMENTS

FIG. 1 shows a test installation 1. This installation 1 is intended to measure the behavior of a domestic electric power supply network 2. The domestic electric power supply 2 is typically powered through an electric meter 3 connected to a general electric supply line 4 belonging to an electricity supplier. The installation 1 includes a traditional dwelling 5, called the residence hereinbelow. The dwelling 5 includes several rooms such as 6 to 8, separated from one another by interior walls such as 9 and 10. Power outlets such as 11 to 16 mounted on the interior walls 9 and 10 and on the walls of the dwelling 5, are connected to the domestic electric power supply network 2. The electric network 2 is thus the network whose behavior is to be measured, especially when different items of electrical household equipment are connected to it.

For example, in a living room 6 there is a television receiver 17 and a floor lamp 18 that may be of different types (halogen, which consumes a lot of power, or neon, which produces many parasites). In a kitchen 7, only a stovetop with four heating elements such as 19 is shown. However, the kitchen 7 may include other equipment such as a refrigerator, an oven, or a washing machine for linens or dishes. In an office 8 is shown a microcomputer 20 symbolizing such a machine with all of its peripherals (not shown). The microcomputer 20 is also linked to a telephone jack 21 that transmits information, particularly in DSL mode (A, V, X, etc.).

In the dwelling 5 the number of outlets such as 11 to 16 is limited, corresponding to typical equipment. This limitation leads to the use of removable multiple-outlet extensions, linked or not to an outlet by a cable end, so as also to test the interference caused by the use of this type of accessories.

The dwelling 5 is located above a slab 22, typically a concrete slab, reinforced with steel rebars. not shown. Below the slab 22 and the residence 5 is a garage 23, in which the electric meter 3 is placed, for example. According to the disclosed embodiments, opposite each power outlet 11 to 16, which are distributed in all of the rooms of the dwelling, there is an open channel such as 24 to 28. These channels 24 to 28 in practice are openings passing through the slab 22, in one example of circular cylindrical shape with a diameter of the order of 8 to 10 cm. These channels open beneath the slab above a cable trunk 29, in this case suspended beneath the slab 22 by slings, not shown. These slings can be simple straps bolted into the ceiling of the garage 23. In other respects, for the building to retain its fire safety the channels 24 to 28 can be obstructed after insertion of the cables by plugs, for example inflatable and fireproof plugs, and preventing any passage of gas between the level of the dwelling 5 and the garage 23. The plugs are also removable.

In this way it is possible to make available measuring instruments such as 31 to 33, either opposite apparatus such as 17 to 20 to be tested, or preferably in parallel with the power outlets 11 to 16 to which these items of apparatus are linked, respectively. Connectors such as 34 to 36 link the items of apparatus 31 to 33 to measurement signal processors located in a test laboratory 37 either directly or indirectly contiguous to the residence 7. The connections 34 thus pass through the channels and are supported beneath the slab 22 by the cable trunks 29. Of course to ascend again to the test laboratory 37, individual channels, or alternatively a passageway 38, permit having all of the connecting cables of the measuring apparatus 31 to 33 reascend. In this way, it can be seen that on the one hand, this avoids encumbering the floor of the residence 5 with a lot of tangled measurement cables, which would distort the results of measurement depending on their various positions as a function of their placements.

Also, in this way the test installation is endowed with very good reproducibility of measurements: the measuring apparatus 31 or 32 is thus naturally placed at definite positions so that the measurements are comparable from one apparatus 17 to 20 to be tested to another, since the measuring apparatus 31 to 32 is always placed in the same position, even if this apparatus is placed in this position at long time intervals, for example several months. The natural replacement of all of this measuring equipment and all of the connections 34 to 36 always in the same positions assures good reproducibility of the installation.

The test installation of the disclosed embodiments of course preferably has an adjoining test laboratory: the laboratory 37. Otherwise, the problem of processing the measurements could be solved differently, for example by saving in memory the signals distributed on the network 2 and processing them later in any laboratory whatsoever.

The laboratory 37 essentially contains the instruments 39 and 40 for processing the measurements transmitted through the connections such as 34 to 36. Preferably, an antechamber 41 is located between the laboratory 37 and the test dwelling 5. The antechamber 41 is also linked by channels or passageways 42 and 43 to the cable trunk 29. Thus, the laboratory 37 and the antechamber 41 are preferably located on the same upper level of the slab 22 as the residence 5. The antechamber 41 contains the instruments 44, 45 for validation of the measurements. The antechamber 41 may possibly be equipped with an instrument to format the measurements made by the measuring instruments 31 to 33, in other words equipped with devices to quantify, digitize, and store these measurements so as to have a memory bank of measurements to be processed later.

The instruments 39 and 40 for processing the measurement signals and those 44 to 45 for validating these signals are powered by an electric system preferably independent of the electric system that powers the residence 5. To this end, the test laboratory 37 and the antechamber 41 are electrically powered through an electric meter 46 linked to a different electric power line, even on the same three-phase line 4 in single phase, on another phase than that which powers the residence 5.

The test laboratory 37 also preferably has an independent test bench 47. This test bench 47 has an electric distribution panel 48. The panel 48 is equipped with a multitude of electric power outlets such as 49 to 51. Each outlet 49 to 51 is linked to a common electric power line 52 through a branch such as 53 to 55, respectively. Each branch is connected in series with a switch 56 6o 58, respectively, between the outlet 49 to 51 and the branch connection to the line 52. The branches 53 to 55 have different lengths. These different lengths are of the order of those found in a residence such as 5. In an example, the bench 47 has 40 outlets such as 49 to 51.

Thus with a test bench like 47, it is possible to simulate in reduced format, possibly transportable, the behavior of any dwelling whatsoever. To complete the use of the bench 47, it has an injector 59 linked to the common line 52. The injector 59 is intended to inject an electric power supply of classical type, typically 220 volts or 110 volts at 50 or 60 Hertz. Otherwise the bench 47 can be linked to a public electric power supply line such as 4, particularly through an intermediate auxiliary electric meter 60.

Alternatively, the injector 59 operates as follows. A protocol is provided to start and to stop the equipment to be tested 17 to 20 in the residence 5 using a remote control command P. For example, this protocol is spread out over a duration of 24 hours, corresponding to a significant time of domestic utilization. Using measuring equipment 31 to 33, the electric signals present on the electric line 2 are detected as this protocol transpires. For example, this detection can be accomplished in the validation and memory apparatus contained in the antechamber 41. These signals are saved in memory, for example, in a memory 61 for electrical events under the control of a microprocessor (not shown). In an example, the memory 61 is located in the test laboratory and is in communication with a program memory 62. The memory 62, also under the control of the microprocessor, is able to run two programs, first a protocol program 63 distributing the commands P to the different items of equipment 17 to 20, and second an injection program 64 to energize the electric power supply line 52 using the injector 59 with an electric power supply respecting the electric supply events stored in the memory 61. To this end, the injector 59, the memories 61, 62, and preferably the processing instruments 39 and 40 and those for validation memory 44 and 45, are linked to one another through a bus 65 for addresses, commands, and data linked to the microprocessor and to its control peripherals, not shown.

With a test bench like 47, it is accordingly possible, especially having access to events stored in the memory 61, to put the test panel 48 in action on each of its outlets and with differences of lengths, of electric power signal distributions corresponding to realistic utilizations, on the one hand, and above all with easy reproducibility since the memory 61 can be rerun a number of times. It is sufficient under these conditions to test an apparatus such as 17 to 20, to connect it to one of the outlets 49 to 51 of the panel 48 to measure its functioning under actual and completely controlled conditions. These measurements will also be carried out by measuring instruments of the same type as 31 to 33.

The measuring instruments such as 31 to 33 are preferably not powered in the residence by the electric network 3 to be tested. They are preferably supplied by a different electric power supply, particularly using a different electric power meter, especially using an auxiliary electric meter 65. The test installation of the disclosed embodiments thus preferably includes at least three independent electric systems: the network passing through the meter 3 for the residence 5, the network passing through a meter 46 for the processing apparatus and possibly the validation apparatus, and the network passing through the meter 65 for the measuring instruments 31 to 33. To account for any possible losses of power supported by the network 2 whose effects are to be measured, the meter 46 is followed downstream by a power inverter 66 capable of supplying all of the processing and validation instruments of the laboratory 37 and of the antechamber 41. Accordingly, it is possible in this way to measure the behavior of the different equipment to be tested in case of loss of power from the linkage 4. The test bench 47, for its part, can possibly be powered through a meter 60, as indicated previously.

The signals stored in the memory 61 can be stored by different methods. They may be stored as a function of the temporal history with adequate quantification at a frequency, for example 8 Khz considering the alternating electric power signals at 50 or 60 Hertz. However, the quantification sampling can be carried out at a considerably higher frequency so as to take into account the transitory high-frequency interferences. In this regard, the recording will be broadband. The signals can preferably be measured in a spectral form, with a logic word in the memory 61 corresponding to each instant, representative of the different amplitudes of the spectral components of the signal detected as present at this instant.

In the first case, the injector 59 has a simple low-pass filter (with internal cutoff frequency lower than the sampling frequency). This low-pass filter is powered by the temporal sampled power signals. The output of this low-pass filter regulates the power signal delivered by the meter 60 in the injector 59. In the second case, the injector 59 has a rapid Fourier transform device upstream from the low-pass filter that permits transformation of the stored spectral components into temporal sampled components.

The implementation of the protocol 63 can be accomplished manually. In this case, a physical person present in the residence 5 can be instructed to shut down the different items of equipment 17 to 20 depending on a daily program that has been communicated to him in advance. It will be noted that this protocol can be started only once, and the corresponding electrical events stored in the memory 61 can consequently be used on the independent test bench 47 as often as desired, to test any type of equipment (especially, but not necessarily, electronic communication equipment) to be able to compare the functioning of these various items of equipment with one another. Proceeding in this way, with this test protocol, leads to the creation of a standard of events from the utilization of these items of equipment. Such a standard is of a nature to increase the reliability and the functioning of the equipment manufactured by different manufacturers.

The test laboratory 37 thus presented is a domestic type laboratory, in other words it is intended for measuring the functioning of equipment that is itself intended for domestic use, especially in individual homes, or alternatively in businesses. As opposed to this domestic laboratory 37, the installation also includes a professional laboratory 67 intended for measuring the functioning of electrical or radio-electric signal transmitters, particular signals of the multimedia communication type intended for items of equipment 17 to 20. The laboratory 67 is thus intended for measuring the functioning of modems made available for teledistribution or telecommunication operators, whether distribution is radio-electric or wired (for the latter by special line in frequency multiplexed DSL mode, or by electric power lines).

The test laboratory 67 is thus intended for measuring the functioning of equipment of the transmitter type such as 68. This transmitter equipment can be linked to transmission antennas 69 located above the roof of the residence 5, of the antechamber 41, of the test laboratory 37, or of the transmission laboratory 67, for example. The transmitter antennas 69 are possibly located outside of the test installation 1. The antenna 69 is preferably placed at the peak of the installation 1 and it is linked to the transmitters 68 through a trap-door access to the roof. Alternatively, the transmitters 66 are linked to a transmission line 70 via an intermediate line extension 71. The line extension 71 consists, for example, of a coil of cable 72 in series with a line adapter 73. It is also known how to simulate the behavior of a long line with the adapter 73. It is possible to impart parameters to the adapter 73 to give the line 70 a behavior corresponding to a desired line length. The line 70 is also linked to the connector 21.

In this way, both the functioning of transmitters such as 68 and the functioning of receivers such as 17 or 20 can be measured in a realistic way. In other respects, the antennas 69 transmit signals that are received by the corresponding antennas 74 of receiving equipment 17 located in the residence 5. Of course other types of transmission can be envisioned, particularly coaxial transmissions to simulate the functioning of cable distribution. It is also possible to envision optical fiber transmissions by making available in the laboratory 67 and the residence 5 transmitters and receivers for light. In this way, the installation can be used to test the functioning of a transmission and reception chain from end to end.

Preferably, the test laboratory 67 permits measuring the functioning of electric power line transmission inside the residence 5, possibly transmissions by electric power lines over the electric power line 4 itself. In this regard, to avoid the mutual electrical pollution of the various networks by one another, each of them is equipped with a separator filter such as 75 to 78 that prevents signals superimposed on one electric system from being transmitted to the other.

So as to permit all of the connections imaginable, the cable trunk 29 is linked also to a mixer rack 79, preferably in the garage, that permits, if it is felt necessary, connecting certain particular equipment to be tested 17 to 20 to processing equipment 39 to 40, or validation equipment 44 to 45, depending on the need, without having to have tangles of connecting cables in the antechamber 41 and/or in the laboratory 37 and/or in the laboratory 67. The mixer rack 79 permits orienting the signals on the different equipment.

Although it is not shown, the installation 1 can include a third laboratory, the visitor laboratory, in which the different experiments, protocols, and equipment used to make these measurements are exhibited, to permit an explanation addressed to the particular manufacturers of equipment who want to have their equipment tested, without disturbing the operation of the laboratory and while completely preserving the operating secrets of the equipment tested.

Each room 6 to 8 of the dwelling 5 has its own mark such as 81 to 83. This mark serves to designate a place where certain of the measuring equipment should preferably be placed. These placements essentially concern the measurements of electromagnetic radiation. Actually, the laboratory can also be used, besides measuring the communications capabilities of the equipment tested F, to measure their electromagnetic compatibilities. The measuring equipment 31 to 33 thus placed in positions 81 to 83, always in the same places, assures good reproducibility of the measurements made. The marks 81 to 83 preferably can be positioned at the center of the rooms 6 to 8 of the dwelling 5.

What is claimed is:

1. Installation for testing electrical behavior, including a test laboratory, comprising:
a test bench located in the laboratory, powered by a first electric network electrically independent of a second electric power supply network for measuring equipment of the laboratory,
in this bench, an electrical distribution panel equipped with a set of outlets,
with each outlet being linked to the first network through a branch,
with each branch being in series with a branch switch,
with the lengths of the branches being different to simulate with this test bench a behavior analogous to that of an electrical network to be tested.

2. Installation pursuant to claim 1, further comprising:
domestic electrical equipment in the rooms of a dwelling of the type of communication, kitchen, and/or laundry equipment, linked to a third electrical supply network of this dwelling,
a test protocol corresponding to placing these various items of domestic electrical equipment progressively in service,
a broadband device for measuring and recording an electric power supply signal present during the implementation of this protocol on the third electric power supply network of this dwelling and producing a recorded electrical signal, and
a generator connected to the first network that supplies the bench and is capable of injecting into it an electrical signal corresponding to the recorded electrical signal.

3. Installation pursuant to claim 2, further comprising means for representing the recorded signal by a computer file of electrical perturbations.

4. Method for measuring the behavior of an electrical apparatus comprising:
measuring the development of an electric power supply in a network with a test laboratory,
storing a signal of the electric power supply in memory with a broadband recorder, and
injecting the signal into a control network of the test laboratory equipped with a test bench to which is connected the electrical apparatus whose behavior is to be measured.

5. Method pursuant to claim 4, wherein the test bench located in the test laboratory is powered with a power supply electrically independent of an electric power supply for measuring apparatus of the test laboratory.

6. Method pursuant to claim 4, wherein:
an electric distribution panel of a set of outlets is mounted in the bench,
each outlet is linked to a common independent electric power supply line through a branch,
each outlet is in series with a branch switch,
the branch lengths are different to simulate with this test bench a behavior analogous to that of the electrical network to be tested,
the common independent electric power supply line is powered with the stored electric power supply signal.

7. Method pursuant to claim 4, wherein:
the electric power supply signal is stored in the form of a computer file of electrical perturbations measured on the domestic electric network, and
an injector is guided by the information contained in the file.

8. Use of the device pursuant to claim 1 to test the functioning of a transmission and reception chain from end to end.

9. Use of the device pursuant to the method of claim 4 to test the functioning of a transmission and reception chain from end to end.
